(19) United States
(12) Patent Application Publication
(10) Pub. No.: US 2017/0115158 A1
(43) Pub. Date: Apr. 27, 2017

(54) SEMICONDUCTOR WAFER WEIGHING APPARATUS AND METHODS

(71) Applicant: METRYX LIMITED, Almondsbury, Bristol (GB)

(72) Inventors: Robert John WILBY, Almondsbury, Bristol (GB); Adrian KIERMASZ, Almondsbury, Bristol (GB)

(73) Assignee: METRYX LIMITED, Almondsbury, Bristol (GB)

(21) Appl. No.: 15/301,661

(22) PCT Filed: Mar. 23, 2015
(86) PCT No.: PCT/GB2015/050851

§ 371 Date: Oct. 3, 2016

(30) Foreign Application Priority Data
Apr. 2, 2014 (GB) 1405926.5

(51) Int. Cl. G01G 23/10; H01L 21/67; H01L 21/66; G01G 17/00

(52) U.S. Cl. CPC G01G 23/10; G01G 17/00; H01L 21/67253; H01L 22/12

(57) ABSTRACT

A semiconductor wafer weighing apparatus comprises: a weight force measuring device for measuring a weight force of a semiconductor wafer; and control means configured to control an operation of the apparatus based on detection of acceleration of the apparatus or of a semiconductor wafer loaded on the apparatus by a detector for detecting acceleration of the apparatus or of a semiconductor wafer loaded on the apparatus; wherein: the control means is arranged to determine an error in the output of the weight force measuring device caused by an acceleration of the apparatus or of a semiconductor wafer loaded on the apparatus, using a predetermined relationship that matches the error in the output of the weight force measuring device to acceleration of the apparatus or of a semiconductor wafer loaded on the apparatus for different accelerations of the apparatus or of a semiconductor wafer loaded on the apparatus.

### FIELD OF THE INVENTION

The present invention relates to a semiconductor wafer weighing apparatus.

The present invention also relates to a semiconductor wafer weighing method.

In addition, the present invention relates to a method of characterising the response of a weight force measuring device of a semiconductor wafer weighing apparatus to acceleration of the weight force measuring device or of a semiconductor wafer loaded on the weight force measuring device.

### BACKGROUND OF THE INVENTION

Microelectronic devices are fabricated on semiconductor (e.g. silicon) wafers using a variety of techniques, e.g. including deposition techniques (CVD, PECVD, PVD, etc.) and removal techniques (e.g. chemical etching, CMP, etc.). Semiconductor wafers may be further treated in ways that alter their mass, e.g. by cleaning, ion implantation, lithography and the like.

Depending on the device being manufactured, each semiconductor wafer may be passed sequentially through hundreds of different processing steps to build up and/or to remove the layers and materials necessary for its ultimate operation. In effect, each semiconductor wafer is passed down a production line. The nature of semiconductor manufacturing means that certain processing steps or sequences of steps in the production flow may be repeated in a similar or identical fashion. For example, this may be to build up similar layers of metal conductors to interconnect different parts of the active circuitry.

To ensure consistency and interoperability of semiconductor equipment used in different factories, standards are adopted throughout the majority of the semiconductor manufacturing industry. For example, standards developed by Semiconductor Equipment and Materials International (SEMI) have a high degree of market uptake. One example of standardisation is the size and shape of the semiconductor (silicon) wafers: typically for volume production they are discs having a diameter of 300 mm. However, some semiconductor (silicon) wafers (typically used in older factories) are discs having a diameter of 200 mm.

The cost and complexity of the processing steps required to produce a completed silicon wafer, together with the time that it takes to reach the end of the production line where its operation can be properly assessed, has led to a desire to monitor the operation of the equipment on the production line and the quality of the wafers being processed throughout processing, so that confidence in the performance and yield of the final wafers may be assured.

Wafer treatment techniques typically cause a change in mass of the semiconductor wafer (e.g. at or on the surface of the semiconductor wafer or in the bulk of the semiconductor wafer). The configuration of the changes to the semiconductor wafer are often vital to the functioning of the device, so it is desirable for quality control purposes to assess wafers during production in order to determine whether they have the correct configuration.

Specialist metrology tools may be used within the production flow so that monitoring is conducted soon after the relevant process of interest and usually before any subsequent processing, i.e. between processing steps.

Measuring the change in mass of a semiconductor wafer either side of a processing step is an attractive method for implementing product wafer metrology. It is relatively low cost, high speed and can accommodate different wafer circuitry patterns automatically. In addition, it can often provide results of higher accuracy than alternative techniques. For example, on many typical materials, thicknesses of material layers can be resolved down to an atomic scale. The wafer in question is weighed before and after the processing step of interest. The change in mass is correlated to the performance of the production equipment and/or the desired properties of the wafer.

Processing steps carried out on semiconductor wafers can cause very small changes in the mass of the semiconductor wafer, which it may be desirable to measure with high accuracy. For example, removing a small amount of material from the surface of the semiconductor wafer may reduce the mass of the semiconductor wafer by a few milligrams, and it may be desirable to measure this change with a resolution of the order of ±10 μg or better. Semiconductor wafer metrology methods and apparatus that are capable of measuring the change in mass of a semiconductor wafer to a resolution of around ±0.1 μg are in development, and methods and apparatus with a resolution of around ±10 μg are commercially available.

### SUMMARY OF THE INVENTION

The present inventor has realised that weight measurements obtained by a semiconductor wafer weighing apparatus (in particular an apparatus that measures the weight force of a semiconductor wafer due to gravity, i.e. a gravimetric force of a semiconductor wafer) may be adversely affected by acceleration of the semiconductor wafer weighing apparatus or of a semiconductor wafer loaded on the apparatus. For example, acceleration of the apparatus or of a semiconductor wafer loaded on the apparatus may be caused by vibration (e.g. forward and backwards, and/or up and down, and/or side to side movement) of the apparatus or of a semiconductor wafer loaded on the apparatus.

A semiconductor wafer weighing apparatus normally has a force measuring device, such as a balance (e.g. a microbalance) or a load cell, which measures the force of the semiconductor wafer. Any acceleration of the force measuring device or of a semiconductor wafer loaded on the force measuring device, e.g. due to vibration of the semiconductor wafer weighing apparatus, may lead to acceleration forces being applied to the weight force measuring device. The weight force measuring device may measure these acceleration forces in the same way as it measures weight forces, which may lead to erroneous weight force measurements being recorded.

Therefore, any acceleration of the weight force measuring device or of a semiconductor wafer loaded on the weight force measuring device during measurement of the weight force of the semiconductor wafer may lead to an error in the measured weight force of the semiconductor wafer, due to the additional acceleration force being measured by the weight force measuring device.

The present inventor has further realised that vibrations of the semiconductor wafer weighing apparatus or of the semiconductor wafer having a period of the order of the measurement time of the semiconductor wafer weighing apparatus may be particularly problematic, in that such vibrations may cause more significant errors. For example, the measurement time of the semiconductor wafer weighing apparatus (i.e. the time taken to perform one weight measurement) may be of the order of approximately 10 seconds. High frequency vibrations, for example vibrations having a period of the order of a second or less, may not cause a significant error in the measurement output of the semiconductor wafer weighing apparatus. This may be because the effects of such a vibration may effectively be filtered or averaged out over the measurement time period. In addition, or alternatively, this may mean that different measurements made at different times may be affected in the same way by the vibration. This is important when performing comparative measurements in which two different weight measurements are subtracted, for example in which the weight of a semiconductor wafer after processing is subtracted from the weight of the semiconductor wafer before processing to determine the weight change due to the processing, because the errors due to the vibrations may therefore substantially cancel (subtract) out.

Low frequency vibrations, such as a vibration having a period of the order of 10 seconds or more, for example vibrations due to an earthquake or due to the effects of wind on a building or structure, may be more problematic when performing weight measurements with a semiconductor wafer weighing apparatus. With such vibrations the effects of the vibrations may not cancel out over the measurement time period. In addition, or alternatively, different measurements made at different times may be affected in different ways by the vibration. For example, when performing comparative measurements in which two different weight measurements are subtracted to determine the weight change, if one of the measurements is taken at a time when the acceleration is high in magnitude, so that there is a larger error in the weight measurement, and the other of the measurements is taken at a time when the acceleration is low in magnitude, so that there is a smaller error in the weight measurement, then a significant error will remain when the two weight measurements are subtracted (because the errors in the weight measurements do not cancel/subtract out). A similar error may occur when the accelerations for the two measurements are in opposite directions, i.e. one of the accelerations is positive (for example an upwards acceleration) and the other acceleration is negative (for example an upwards deceleration, or a downwards acceleration).

The inventor has also realised that many passive damping techniques used with some other types of metrology apparatus convert or translate high frequency vibrations to low frequency vibrations. Such passive damping techniques may therefore be unsuitable for semiconductor wafer metrology apparatus, where low frequency vibrations may be more problematic (in terms of the size of the resulting error) than high frequency vibrations (for the reasons discussed above).

The present inventor has realised that it may therefore be advantageous to monitor acceleration of a semiconductor wafer processing apparatus or of a semiconductor wafer loaded on the apparatus and to control the operation of the wafer processing apparatus accordingly.

In the following, the term “acceleration” may mean any change in velocity, and may cover both an increase in velocity and a decrease in velocity. In other words, the term “acceleration” in the following may also include “deceleration” (i.e. a decrease in velocity). Depending on the context, in the following the term “acceleration” may be used to refer to the magnitude of the acceleration (i.e. a scalar quantity) or to the magnitude and the direction of the acceleration (i.e. a vector quantity).

At its most general, the present invention relates to controlling an operation of a semiconductor wafer weighing apparatus based on the output of a detector for detecting acceleration of the apparatus or of a semiconductor wafer loaded on the apparatus.

According to a first aspect of the present invention, there is provided a semiconductor wafer weighing apparatus comprising: control means configured to control an operation of the apparatus based on detection of acceleration of the apparatus or of a semiconductor wafer loaded on the apparatus by a detector for detecting acceleration of the apparatus or of a semiconductor wafer loaded on the apparatus.

Acceleration of the apparatus or of a semiconductor wafer loaded on the apparatus may mean positive or negative acceleration (i.e. it may include deceleration as well as acceleration). Acceleration may mean any change in velocity.

Detecting acceleration may comprise detecting the presence of acceleration. Alternatively, or in addition, detecting acceleration may comprise determining a direction of the acceleration. Alternatively, or in addition, detecting acceleration may comprise determining a magnitude of the acceleration. Detecting acceleration may also comprise detecting the time variation of the acceleration.

In some embodiments, only acceleration of the apparatus may be detected. In other embodiments, only acceleration of a semiconductor wafer loaded on the apparatus may be detected. In other embodiments, accelerations of the apparatus and of a semiconductor wafer loaded on the apparatus may both be detected (simultaneously or separately).

With the apparatus according to the first aspect of the present invention, acceleration of the apparatus or of a semiconductor wafer loaded on the apparatus that may cause an erroneous weight measurement (for example acceleration of the apparatus or of a semiconductor wafer loaded on the apparatus that may cause an erroneous weight force measurement due to the presence of acceleration forces on a weight force measuring device of the apparatus) may be detected by the detector.

An operation of the apparatus is controlled based on the detection of acceleration of the apparatus or of a semiconductor wafer loaded on the apparatus. The operation may be controlled based on specific information about the acceleration, such as its magnitude and/or direction and/or duration. Thus, when acceleration of the apparatus or of the semiconductor wafer loaded on the apparatus that may cause an erroneous weight measurement is detected, appropriate action may be taken by controlling an operation of the apparatus. Therefore, the effects of acceleration of the apparatus or of a semiconductor wafer loaded on the apparatus may be identified or mitigated. As discussed above, acceleration of the semiconductor weighing apparatus or of a semiconductor wafer loaded on the apparatus may occur due to e.g. vibration of the semiconductor weighing apparatus, for example forwards and backwards movement, and/or side to side movement, and/or up and down movement or some combination of these three movements (i.e. movement that can be resolved into movement in either direction along one or more of three mutually perpendicular axes). The term “vibration” may mean a periodic oscillation of the apparatus, or an aperiodic or irregular movement of the apparatus. Vibration may mean any number of oscillations of the apparatus, for example vibration may mean a single forwards and backwards movement of the apparatus. Acceleration force(s) may also be applied to the apparatus or to a semiconductor wafer loaded on the apparatus by an impulse force applied to the apparatus or to a semiconductor wafer loaded on the apparatus.

The apparatus according to the first aspect of the present invention may have any one, or, to the extent that they are compatible, any combination of more than one, of the following optional features.

The control means may be configured to control the apparatus to identify a measurement (e.g. a weight force measurement, or measurements) that may have been affected by acceleration of the apparatus or of a semiconductor wafer loaded on the apparatus.

In other words, the control means may be arranged to identify a measurement that may have a measurement error caused by the effects of acceleration of the apparatus or of a semiconductor wafer loaded on the apparatus, such as a measurement that may have a measurement error with a magnitude above a predetermined threshold, or a measurement that may have a measurement error of any magnitude.

For example, the control means may be arranged to control the apparatus to identify a measurement that was performed at the same time that acceleration of the apparatus was detected.

The control means may be arranged to control the apparatus to notify an operator of the apparatus or a host or controller of the apparatus that a measurement may have been affected by acceleration of the apparatus or of a semiconductor wafer loaded on the apparatus, for example through a visual or audible notification or indication, such as by playing a sound, illuminating a light, or by indicating the presence of acceleration or of a possible error in the measurement result on a display for displaying the measurement result of the apparatus.

The control means may be arranged to control a time at which the apparatus performs a measurement based on the output of the detector. For example, the control means may be arranged to control a time at which the apparatus performs the measurement so as to reduce or minimise the effects of acceleration on the measurement. For example, the control means may be arranged to control the apparatus to perform a measurement when the effects of an acceleration on the measurement are expected to be below a predetermined threshold, for example when the magnitude of an acceleration is below a predetermined threshold.

The control means may be arranged to control the apparatus to perform a measurement when the detector detects substantially zero acceleration of the apparatus or of a semiconductor wafer loaded on the apparatus. For example, the acceleration of the apparatus or of a semiconductor wafer loaded on the apparatus may be zero where there is no vibration of the apparatus or of a semiconductor wafer loaded on the apparatus (i.e. where the apparatus or the semiconductor wafer is stationary). In addition, the acceleration of the apparatus or of a semiconductor wafer loaded on the apparatus may be zero where there is a periodic vibration of the apparatus or the semiconductor wafer and the apparatus or the semiconductor wafer is approximately at the mid-point of an oscillation and moving at constant velocity.

Performing a measurement when substantially zero acceleration is detected may be advantageous because there may be substantially zero acceleration forces on the apparatus or on a semiconductor wafer loaded on the apparatus at that time. Therefore, where the apparatus comprises a weight force measuring device for measuring a weight force of the semiconductor wafer, the weight force measured by the weight force measuring device may not include any acceleration forces in addition to the weight force of the semiconductor wafer. Therefore, errors in the measurement output of the apparatus due to acceleration of the apparatus or of a semiconductor wafer loaded on the apparatus may be avoided, removed or reduced.

The control means may be configured to control the apparatus to perform a measurement at a null point of an oscillating acceleration of the apparatus or of a semiconductor wafer loaded on the apparatus. As above, at a null point of the oscillation the acceleration will be zero and therefore errors in the measurement output of the apparatus due to acceleration of the apparatus may be avoided, removed or reduced.

Alternatively, where there are more than one sources of vibration, or vibrations having different periods or directions, applied to the apparatus or to a semiconductor wafer loaded on the apparatus, the control means may be configured to control the apparatus to perform a measurement at a null point or a minimum of the sum of the different vibrations (e.g. at a time where the different vibrations destructively interfere so that the resultant acceleration is substantially zero, or a minimum). In some embodiments, the control means may be configured to control the apparatus to perform a measurement at a null point or a minimum of the sum of the different vibrations in a direction parallel to a weight measurement direction of the apparatus (e.g. vertical in many apparatus). Accelerations of the apparatus or of a semiconductor wafer loaded on the apparatus in a direction parallel to the weight measurement direction may have the most significant effect on the output of the apparatus.

The apparatus may comprise an active damping device for actively damping acceleration of the apparatus or of a semiconductor wafer loaded on the apparatus; and the control means may be arranged to control the active damping device to actively damp acceleration of the apparatus or of a semiconductor wafer loaded on the apparatus based on the output of the detector. Actively damping the acceleration of the apparatus or of a semiconductor wafer loaded on the apparatus may mean actively reducing, restricting or preventing acceleration of the apparatus or of a semiconductor wafer loaded on the apparatus. For example, actively damping the acceleration of the apparatus or of a semiconductor wafer loaded on the apparatus may mean actively damping vibration of the apparatus or of a semiconductor wafer loaded on the apparatus, for example by actively reducing, restricting or preventing vibration of the apparatus or of a semiconductor wafer loaded on the apparatus. Actively damping acceleration of the apparatus or of a semiconductor wafer loaded on the apparatus may comprise actively dissipating energy from the apparatus or from the semiconductor wafer, for example actively dissipating kinetic energy from the apparatus or from the semiconductor wafer, e.g. using an external means such as an actuator.

The active damping device may actively damp the acceleration by actively applying forces to the apparatus or to the semiconductor wafer to counter-act or to reduce the effect of acceleration forces applied to the apparatus or to the semiconductor wafer, e.g. by applying forces to the apparatus or to the semiconductor wafer using an electronically controlled actuator. The control means may control the timing and magnitude of forces applied to the apparatus or to the semiconductor wafer by the active damping device so as to actively damp (i.e. to reduce in magnitude) acceleration or vibration of the apparatus or of the semiconductor wafer, for example by dissipating energy from the apparatus or from the semiconductor wafer. Therefore, the effects of acceleration of the apparatus or of a semiconductor wafer loaded on the apparatus may be reduced or removed by detecting the acceleration of the apparatus or of the semiconductor wafer and by controlling the active damping device based on the detection of the acceleration so as to actively damp the acceleration of the apparatus or of the semiconductor wafer.

The active damping device may comprise a piezoelectric actuator. A piezoelectric actuator may be particularly suited for use as an active damping device in the present invention. Of course, other types of actuator may also be used.

Alternatively, or in addition, the control means may be configured to actively damp or to filter a signal output of a weight force sensor of the apparatus to counter-act or to reduce the component of the signal due to acceleration of the apparatus or of a semiconductor wafer loaded on the apparatus, based on the output of the detector.

The control means may be arranged to control the apparatus to substantially correct a measurement result of the apparatus for the effect of an acceleration of the apparatus or of a semiconductor wafer loaded on the apparatus. The acceleration may be an instantaneous acceleration at that moment, or a predicted acceleration based on previously detected information about preceding accelerations.

For example, where it is determined that a measurement result has been affected by acceleration of the apparatus or of a semiconductor wafer loaded on the apparatus, the control means may be arranged to control the apparatus to determine an error in the measurement result due to the effect of the acceleration and to correct the measurement result for the determined error. Determining the error in measurement result may comprise calculating or predicting the error in the measurement result, or looking up the error in the measurement result based on the output of the detector and e.g. a data file in which values for the error in the measurement result are associated with corresponding values for the acceleration of the apparatus or of a semiconductor wafer loaded on the apparatus, for example in a list or a look up table. The values for the acceleration may be instantaneous value, average values, representative values or predicted values.

The apparatus may comprise a weight force measuring device for measuring a weight force of a semiconductor wafer; and the control means may be arranged to control the apparatus to determine an error in the output of the weight force measuring device caused by an acceleration of the apparatus or of a semiconductor wafer loaded on the apparatus.

For example the weight force measuring device may comprise a balance, or a microbalance, or a load cell.

As discussed above, acceleration of the apparatus or of a semiconductor wafer loaded on the apparatus may lead to acceleration forces being applied to the weight force measuring device, and the weight force measuring device may measure the acceleration forces in addition to measuring the weight force of the semiconductor wafer. Thus, the measurement output of the weight force measuring device may correspond to the sum of the weight force of the semiconductor wafer and the acceleration force applied to the weight force measuring device or to the semiconductor wafer loaded on the apparatus at the time the measurement was performed. Therefore, acceleration of the apparatus or of a semiconductor wafer loaded on the apparatus may lead to an error in the weight force measurement of the weight force measuring device, due to the additional acceleration forces being measured. The control means may control the apparatus to determine the error in the output of the force measuring device (i.e. the part of the measurement output of the weight force measuring device that corresponds to the acceleration force). Once the error in the output of the weight force measuring device has been determined, the output of the weight force measuring device may be corrected by subtracting the error from the output, so that the output of the weight force measuring device corresponds solely to the weight force of the semiconductor wafer.

The control means may be arranged to determine the error in the output of the weight force measuring device using a predetermined relationship that matches the error in the output of the weight force measuring device to the acceleration of the apparatus or of a semiconductor wafer loaded on the apparatus, for different accelerations of the apparatus or of a semiconductor wafer loaded on the apparatus.

For example, the predetermined relationship may be an algorithm, or an equation, or a data file, for example a data file comprising a list or a look up table, or some other form of relationship. The predetermined relationship may allow the error in the output of the weight force measuring device to be determined from the acceleration of the apparatus or of a semiconductor wafer loaded on the apparatus. For example, the predetermined relationship may be a data file (e.g. comprising a list or a table) in which a plurality of values of accelerations of the apparatus or of a semiconductor wafer loaded on the apparatus are associated with corresponding values of errors in the output of the weight force measuring device. Alternatively, the predetermined relationship may be an equation or algorithm that outputs an error in the output of the weight force measuring device when an acceleration of the apparatus or of a semiconductor wafer loaded on the apparatus is input into the equation or algorithm. The input acceleration may be an instantaneous, averaged, representative or averaged acceleration.

The apparatus may comprise a detector for detecting acceleration of the apparatus or of a semiconductor wafer loaded on the apparatus; and the control means may be configured to control the operation of the apparatus based on detection of acceleration of the apparatus or of a semiconductor wafer loaded on the apparatus by the detector. In other words, the detector may be a part of the apparatus, e.g. integral to the apparatus.

The detector may comprise a weight force measuring device of the apparatus for measuring a weight force of a semiconductor wafer loaded on the apparatus; and the control means may be configured to control the operation of the apparatus based on detection of acceleration of the apparatus or of a semiconductor wafer loaded on the apparatus by the weight force measuring device. In other words, the weight force measuring device of the apparatus may also be used as a detector to detect acceleration of the apparatus or of a semiconductor wafer loaded on the apparatus, and the operation of the apparatus may then be controlled based on detection of acceleration of the apparatus by the weight force measuring device.

The apparatus may further comprise a weight force measuring device for measuring a weight force of a semiconductor wafer loaded on the apparatus. In other words, the detector may be separate to, or distinct from, the weight force measuring device of the apparatus.

There may also be provided a system comprising the apparatus according to the first aspect of the invention and a detector for detecting acceleration of the apparatus or of a semiconductor wafer loaded on the apparatus; wherein the control means of the apparatus is configured to control an operation of the apparatus based on detection of acceleration of the apparatus or of a semiconductor wafer loaded on the apparatus by the detector. In other words, the detector may not be part of the apparatus, for example it may be physically separate to the apparatus or remote from the apparatus (but in communication with the apparatus, e.g. via a wired or a wireless connection).

The system may comprise a plurality of apparatus according the first aspect of the present invention, the detector may be for detecting acceleration of each of the plurality of apparatus or of semiconductor wafers loaded on the apparatus, and each of the control means of the plurality of apparatus may be configured to control an operation of the apparatus based on detection of acceleration of the apparatus or of a semiconductor wafer loaded on the apparatus by the detector. In other words, a plurality of apparatus may each share the same detector, i.e. a single detector may be used to detect acceleration of a plurality of apparatus or of semiconductor wafers loaded on the apparatus. This may be advantageous where there are a plurality of apparatus in close proximity, for example in a semiconductor wafer fabrication environment in a single building, and where all of the apparatus may be affected in the same way by acceleration, for example where all of the apparatus may be vibrated in the same way by vibration of a building containing the apparatus due to an earthquake or wind. The detector may be incorporated into one of the apparatus, for example the detector may be a weight force measuring device of one of the apparatus for measuring a weight force of a semiconductor wafer loaded on the apparatus.

The detector may comprise: an accelerometer for measuring acceleration of the apparatus or of a semiconductor wafer loaded on the apparatus; or a force sensor for measuring a force applied to the apparatus or to a semiconductor wafer loaded on the apparatus; or a position sensor for measuring a position of the apparatus or of a semiconductor wafer loaded on the apparatus; or a velocity sensor for measuring a velocity of the apparatus or of a semiconductor wafer loaded on the apparatus. Any of these sensors may be used to determine, directly or indirectly, the acceleration of the apparatus or the semiconductor wafer and therefore the acceleration forces experienced by the apparatus or the semiconductor wafer (for example the acceleration forces experienced by a weight force measuring device of the apparatus). Therefore, the outputs of any of these detectors may be used to determine appropriate operation of the apparatus.

The detector may comprise: a weight force measuring device; or a load cell; or a balance; or a piezoelectric sensor; or a mass on a spring; or a capacitance sensor; or a strain sensor; or an optic sensor; or a vibrating quartz sensor. Such sensors may be suitable for directly or indirectly determining acceleration forces that may be measured by the apparatus.

The apparatus may comprise a force measuring device for measuring a force of a semiconductor wafer loaded on the apparatus, and the detector may be configured to detect acceleration of the apparatus or of a semiconductor wafer loaded on the apparatus in a direction parallel to a force measuring direction of the force measuring device. For example, a force measuring device may measure only the component of a force along a particular direction, for example a vertical direction. Components of forces in other directions may not be measured by the weight force measuring device. Therefore, the magnitude of an error in a measurement output of the apparatus may depend on the component of the acceleration (a vector quantity) in the force measuring direction, instead of on the overall magnitude of the acceleration. Therefore, it may be advantageous to detect (e.g. to measure the magnitude of) acceleration of the apparatus or of a semiconductor wafer loaded on the apparatus in a direction parallel to the measuring direction.

According to a second aspect of the present invention there is provided a semiconductor wafer weighing method that comprises: detecting acceleration of a semiconductor wafer weighing apparatus or of a semiconductor wafer loaded on the apparatus using a detector; and controlling an operation of the apparatus based on detection of acceleration of the apparatus or of a semiconductor wafer loaded on the apparatus by the detector.

The advantages of the second aspect of the present invention may be the same as one or more of the advantages of the first aspect of the present invention discussed above.

The method according to the second aspect of the present invention may have any one, or, to the extent that they are compatible, any combination of more than one, of the following optional features. The advantages of the following optional features may be the same as the advantages of the corresponding optional features of the first aspect of the present invention discussed above.

The method may comprise controlling the apparatus to identify a measurement that may have been affected by acceleration of the apparatus or of a semiconductor wafer loaded on the apparatus.

The method may comprise controlling a time at which the apparatus performs a measurement based on the output of the detector.

The method may comprise controlling the apparatus to perform a measurement when the detector detects substantially zero acceleration of the apparatus or of a semiconductor wafer loaded on the apparatus.

The method may comprise controlling the apparatus to perform a measurement at a null point of an oscillating acceleration of the apparatus or of a semiconductor wafer loaded on the apparatus.

The method may comprise controlling an active damping device to actively damp acceleration of the apparatus or of a semiconductor wafer loaded on the apparatus based on the output of the detector.

The active damping device may comprise a piezoelectric actuator.

The method may comprise substantially correcting a measurement result for the effect of an acceleration of the apparatus or of a semiconductor wafer loaded on the apparatus.

The apparatus may comprise a weight force measuring device for measuring a weight force of a semiconductor wafer; and the method may comprise determining an error in the output of the weight force measuring device caused by an acceleration of the apparatus or of a semiconductor wafer loaded on the apparatus.

The method may comprise determining the error in the output of the weight force measuring device using a predetermined relationship that matches the error in the output of the weight force measuring device to an acceleration of the apparatus or of a semiconductor wafer loading on the apparatus, for different accelerations of the apparatus or of a semiconductor wafer loaded on the apparatus.

The method may comprise determining the predetermined relationship in advance by measuring the response of the weight force measuring device to different accelerations of the apparatus of or a semiconductor wafer loaded on the apparatus.

Determining the predetermined relationship in advance may comprise determining the frequency response of the weight force measuring device.

Determining the predetermined relationship in advance may comprise accelerating the weight force measuring device or a semiconductor wafer loaded on the weight force measuring device and measuring the output of the weight force measuring device to different accelerations.

Determining the predetermined relationship in advance may comprise vibrating the weight force measuring device, for example using a piezoelectric actuator.

The apparatus may comprise a detector for detecting acceleration of the apparatus or of a semiconductor wafer loaded on the apparatus; and the method may comprise controlling the operation of the apparatus based on detection of acceleration of the apparatus or of a semiconductor wafer loaded on the apparatus by the detector.

The detector may comprise a weight force measuring device of the apparatus for measuring a weight force of a semiconductor wafer loaded on the apparatus; and the method may comprise controlling the operation of the apparatus based on detection of acceleration of the apparatus or of a semiconductor wafer loaded on the apparatus by the weight force measuring device.

The method may comprise detecting acceleration of the apparatus or of a semiconductor wafer loaded on the apparatus using a detector separate from the apparatus.

The method may comprise detecting acceleration of the apparatus or of a semiconductor wafer loaded on the apparatus using: an accelerometer for measuring acceleration of the apparatus or of a semiconductor wafer loaded on the apparatus; or a force sensor for measuring a force on the apparatus or on a semiconductor wafer loaded on the apparatus; or a position sensor for measuring a position of the apparatus or of a semiconductor wafer loaded on the apparatus; or a velocity sensor for measuring a velocity of the apparatus or of a semiconductor wafer loaded on the apparatus.

The method may comprise detecting acceleration of the apparatus or of a semiconductor wafer loaded on the apparatus using: a weight force measuring device; or a load cell; or a balance; or a piezoelectric sensor; or a mass on a spring; or a capacitance sensor; or a strain sensor; or an optic sensor; or a vibrating quartz sensor.

The apparatus may comprise a force measuring device for measuring a force of a semiconductor wafer loaded on the apparatus; and the method may comprise detecting acceleration of the apparatus or of a semiconductor wafer loaded on the apparatus in a direction parallel to a force measuring direction of the force measuring device.

The present inventor has also realised that it would be advantageous to know how a weight force measuring device of a semiconductor wafer weighing apparatus responds to different accelerations of the weight force measuring device or of a semiconductor wafer loaded on the weight force measuring device, so that when the weight force measuring device is being used to perform a weight measurement, a measurement error of the weight measurement due to an acceleration of the weight force measuring device or of a semiconductor wafer loaded on the weight force measuring device can be determined (e.g. calculated or looked-up) based on a property or properties of the acceleration (for example based on the magnitude and/or the direction of the acceleration).

Therefore, according to a third aspect of the present invention there is provided a method of characterising the response of a weight force measuring device of a semiconductor wafer weighing apparatus to acceleration of the weight force measuring device or of a semiconductor wafer loaded on the weight force measuring device, the method comprising: accelerating the weight force measuring device or a semiconductor wafer loaded on the weight force measuring device; and measuring the output of the weight force measuring device in response to the acceleration.

A semiconductor wafer may be loaded on the weight force measuring device when characterising its response. In some embodiments, the response of the weight force measuring device may be separately characterised with and without a semiconductor wafer loaded on it.

Characterising the response of the weight force measuring device to acceleration of the weight force measuring device or of a semiconductor wafer loaded on the weight force measuring device may mean measuring the output of the weight force measuring device due to acceleration of the weight force measuring device or of a semiconductor wafer loaded on the weight force measuring device for a plurality of different accelerations. For example, characterising the response of the weight force measuring device to acceleration of the weight force measuring device or of a semiconductor wafer loaded on the weight force measuring device may comprise determining how the output of the weight force measuring device changes as the acceleration of the weight force measuring device or of a semiconductor wafer loaded on the weight force measuring device changes.

As mentioned above, characterising the response of the weight force measuring device to acceleration of the weight force measuring device or of a semiconductor wafer loaded on the weight force measuring device may allow the error in the output of the weight force measuring device, due to an acceleration of the weight force measuring device or of a semiconductor wafer loaded on the weight force measuring device when the weight force measuring device is being used to measure the weight force of a semiconductor wafer, to be determined based on the acceleration. Therefore, characterising the response of the weight force measuring device may facilitate or enable correction for the effects of acceleration (e.g. due to vibration) of the weight force measuring device or of a semiconductor wafer loaded on the weight force measuring device when performing measurements of the weight force of a semiconductor wafer.

The weight force measuring device or a semiconductor wafer loaded on the weight force measuring device may be accelerated by vibrating the weight force measuring device or the semiconductor wafer. Vibrating the weight force measuring device or the semiconductor wafer may comprise moving the weight force measuring device or the semiconductor wafer forwards and backwards, and/or up and down, and/or side to side (i.e. in both/either directions along one or more of three mutually orthogonal axes). The vibration may be periodic or may instead be aperiodic or irregular. The vibration may comprise any number of oscillations (a movement in one direction followed by a movement in the opposite direction, the movements possibly being of the same size or possibly being of different sizes). Since vibration of the weight force measuring device or the semiconductor wafer includes changes of velocity and direction of the weight force measuring device or the semiconductor wafer, acceleration forces of different magnitudes and directions are applied to the weight force measuring device or the semiconductor wafer as it is vibrated. Therefore, the output of the weight force measuring device or the semiconductor wafer may be measured for a plurality of different magnitudes and directions of acceleration.

The method may comprise vibrating the weight force measuring device or a semiconductor wafer loaded on the weight force measuring device using a piezoelectric actuator, or some other type of actuator. A piezoelectric actuator may be a suitable way of controllably vibrating the weight force measuring device or the semiconductor wafer at different frequencies.

The method may comprise measuring the output of the weight force measuring device for a plurality of different frequencies of vibration. In other words, the method may comprise vibrating the weight force measuring device or a semiconductor wafer loaded on the weight force measuring device at different frequencies of vibration and measuring the output of the weight force measuring device for the different frequencies of vibration (or for the different accelerations experienced at the different frequencies of vibration). Changing the frequency of vibration may change the magnitudes of acceleration experienced by the weight force measuring device or by the semiconductor wafer.

The method may comprise determining the frequency response of the weight force measuring device. The frequency response of the weight force measuring device may be the Fourier transform of the impulse response of the weight force measuring device. The frequency response of the weight force measuring device may comprise a measure of magnitude and phase of the output of the weight force measuring device as a function of the frequency of the vibration applied to the weight force measuring device. The frequency response of the weight force measuring device may comprise a relationship between the magnitude of the output of the weight force measuring device and the frequency of the vibration applied to the weight force measuring device.

The method may comprise determining a relationship that matches the output of the weight force measuring device to the acceleration of the weight force measuring device or of a semiconductor wafer loaded on the weight force measuring device, for different accelerations of the weight force measuring device or of a semiconductor wafer loaded on the weight force measuring device. For example, the relationship may be an equation or algorithm that outputs the output of the weight force measuring device due to an acceleration of the weight force measuring device or of a semiconductor wafer loaded on the weight force measuring device when that acceleration is input into the equation or algorithm. Alternatively, the relationship may comprise a data file, for example containing a list or a table (e.g. a look-up table), in which a plurality of values of the output of the weight force measuring device due to acceleration of the weight force measuring device or of a semiconductor wafer loaded on the weight force measuring device are associated with corresponding values of the acceleration of the weight force measuring device or of a semiconductor wafer loaded on the weight force measuring device. Thus, the relationship may characterise the response of the weight force measuring device to acceleration of the weight force measuring device or of a semiconductor wafer loaded on the weight force measuring device, and therefore facilitate or enable correction of measurements of the weight force measuring device for the effects of acceleration (or vibration) of the weight force measuring device or of a semiconductor wafer loaded on the weight force measuring device.

According to a fourth aspect of the present invention there is provided a semiconductor wafer weighing apparatus comprising:

control means configured to control an operation of the apparatus based on detection of acceleration of the apparatus or of a semiconductor wafer loaded on the apparatus by a detector for detecting acceleration of the apparatus or of a semiconductor wafer loaded on the apparatus;

wherein the control means is configured to:

predict when a continuously varying acceleration of the apparatus or of a semiconductor wafer loaded on the apparatus will be instantaneously substantially zero; and

control the apparatus to perform a measurement at the predicted time.

The fourth aspect of the present invention may include any one or more of the optional features of the first to third aspects of the present invention set out above. Those optional features are not repeated here for reasons of conciseness. The fourth aspect of the present invention may also, or alternatively, comprise one of more of the following optional features.

In the fourth aspect of the present invention, the control means is configured to predict in advance when a continuously varying acceleration of the apparatus or of a semiconductor wafer loaded on the apparatus will be substantially zero, and to control the apparatus to perform the measurement at the predicted time. A continuously varying acceleration may mean any acceleration that is changing over time, for example an oscillating (periodic or otherwise) acceleration, or an acceleration caused by continuous vibration of the apparatus or semiconductor wafer.

For example, the instantaneous acceleration may be substantially zero at or around a time where the acceleration changes from being positive to negative, or changes from being negative to positive. For example, the acceleration may be instantaneously substantially zero at a null point of a vibration or of an oscillating acceleration.

An advantage of predicting in advance when the instantaneous acceleration will be substantially zero is that it may be possible to more reliably ensure that the measurement is taken at the time at which the instantaneous acceleration will be substantially zero.

For example, the apparatus may have a predetermined response time for performing a measurement, which may, for example, include a predetermined response time of a weight force measuring device of the apparatus, and/or a predetermined response time of the control means. If the control means merely looked at the instantaneous acceleration and sent a control signal at the moment it detects that the instantaneous acceleration becomes zero, the response time of the apparatus will mean that the measurement is not taken until a period of time after the time at which the instantaneous acceleration became zero, by which time the continually varying acceleration may no longer be zero. Thus, the measurement would be taken during an instantaneous acceleration that is not substantially zero and the measurement result would be adversely affected.

In contrast, with the present invention, since the time at which the acceleration will be substantially zero is predicted in advance, the apparatus is able to take action in advance. For example, the control means may be configured to send a control signal instructing a measurement to be performed (e.g. to a weight force measuring device of the apparatus) at the predetermined response time of the apparatus before the predicted time, so that the apparatus performs the measurement at the predicted time and not after the predicted time. Thus, by predicting in advance when the acceleration will be substantially zero, the accuracy of the measurement result may be improved.

The apparatus may be configured to monitor the acceleration of the apparatus or of a semiconductor wafer loaded on the apparatus over a predetermined period of time; and the control means may be configured to use the results of this monitoring to perform the prediction. For example, the results of the monitoring may indicate particular trends or patterns in the acceleration.

The apparatus may be configured to record a plurality of values of the acceleration of the apparatus or of a semiconductor wafer loaded on the apparatus over a predetermined period of time; and the control means may be configured to use the recorded values to perform the prediction. The recorded values may be termed a recent acceleration history, and may characterise the recent acceleration of the apparatus or of the semiconductor wafer.

The control means may have an equation or algorithm into which the recorded or stored historical values of the acceleration are input and which outputs a time when the acceleration will be substantially zero, or a period of time until the acceleration will be substantially zero. The control means may then control the apparatus to perform a measurement at the predicted time or after the predicted period of time.

The control means may be configured to extrapolate from the recorded values to predict when the instantaneous acceleration will be substantially zero.

The control means may be configured to determine an equation that best fits the recorded values and to use this equation to perform the prediction. Essentially, this may correspond to extrapolating from the recorded acceleration history to predict the time at which the acceleration will be substantially zero.

Where the acceleration is periodic, the recorded values may span a period of time equal to or greater than a period of the acceleration.

The control means may be configured to change a state of the apparatus in advance of the predicted time. For example, the control means may be configured to prepare the apparatus for taking a measurement in advance of the predicted time, for example by changing one or more properties of a weight force measuring device of the apparatus in advance of the predicted time, so that the apparatus is ready to take the measurement at the predicted time.

According to a fifth aspect of the present invention there is provided a semiconductor wafer weighing method comprising:

detecting acceleration of a semiconductor wafer weighing apparatus or of a semiconductor wafer loaded on the apparatus using a detector; and

predicting when a continuously varying acceleration of the apparatus or of a semiconductor wafer loaded on the apparatus will be instantaneously substantially zero; and

controlling the apparatus to perform a measurement at the predicted time.

The fifth aspect of the present invention may include any one or more of the optional features of the first to fourth aspects of the present invention set out above. Those optional features are not repeated here for reasons of conciseness. The fifth aspect may also, or alternatively, comprise one or more of the following optional features.

The method may comprise monitoring the acceleration of the apparatus or of a semiconductor wafer loaded on the apparatus over a predetermined period of time; and using the results of this monitoring to perform the prediction.

The method may comprise recording a plurality of values of the acceleration of the apparatus or of a semiconductor wafer loaded on the apparatus over a predetermined period of time; and using the recorded values to perform the prediction.

The method may comprise determining an equation that best fits the recorded values and using this equation to perform the prediction.

The method may comprise changing a state of the apparatus in advance of the predicted time.

### BRIEF DESCRIPTION OF THE DRAWINGS

Embodiments of the present invention will now be discussed, by way of example only, with reference to the accompanying Figures, in which:

FIG. 1 is a schematic illustration of a prior art semiconductor wafer weighing apparatus;

FIG. 2(a) is a schematic illustration of a semiconductor wafer weighing apparatus according to an embodiment of the present invention;

FIG. 2(b) is a schematic illustration of a semiconductor wafer weighing apparatus according to another embodiment of the present invention;

FIG. 3 is a schematic illustration of a semiconductor wafer weighing apparatus according to another embodiment of the present invention;

FIG. 4 (a) is a schematic illustration of an embodiment of a method of characterising the response of a weight force measuring device of a semiconductor wafer weighing apparatus to acceleration of the weight force measuring device or of a semiconductor wafer loaded on the weight force measuring device;

FIG. 4 (b) is a schematic illustration of a further embodiment of a method of characterising the response of a weight force measuring device of a semiconductor wafer weighing apparatus to acceleration of the weight force measuring device or of a semiconductor wafer loaded on the weight force measuring device.

### DETAILED DESCRIPTION OF THE PREFERRED EMBODIMENTS AND FURTHER OPTIONAL FEATURES OF THE INVENTION

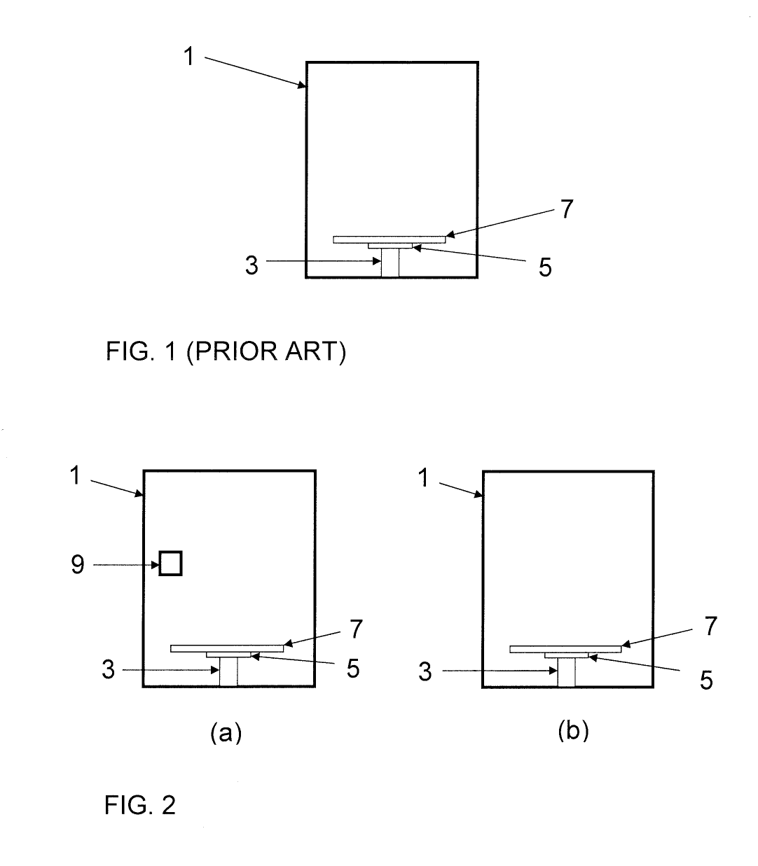

FIG. 1 is a schematic illustration of a prior art semiconductor wafer weighing apparatus, which may be used for e.g. weighing semiconductor wafers being produced by a production line in a semiconductor wafer fabrication facility in order to monitor the fabrication of the semiconductor wafers.

As shown in FIG. 1, the apparatus comprises a measurement chamber 1 that encloses a measurement area of the apparatus. The measurement chamber 1 may restrict or prevent air flow into or out of the measurement area of the apparatus, which may prevent air flows and/or changes in air temperature or pressure from adversely affecting measurements performed by the apparatus.

The measurement area of the apparatus comprises a weight force measuring device 3, which may for example comprise a balance (e.g. an electronic microbalance) or a load cell, for measuring the weight force of a semiconductor wafer 7 loaded on the apparatus. The measurement area of the apparatus also comprises a support 5 for supporting the semiconductor wafer 7 as its weight is being measured by the weight force measuring device 3.

It is to be understood that FIG. 1 is a simplified schematic illustration of some of the features of a semiconductor wafer weighing apparatus so that their function can be easily understood, and that in reality the configuration and appearance of e.g. the weight force measuring device may be significantly different to that illustrated in FIG. 1.

As shown in FIG. 1, in use a semiconductor wafer 7 is placed on the support 5 so that its weight can be measured by the weight force measuring device 3. The measurement chamber 1 may have one or more openings (not shown) through which a semiconductor wafer can be inserted into or removed from the measurement chamber 1. The one or more openings may be sealable by a door or covering (not shown) when not in use.

When a semiconductor wafer 7 is supported on the support 5, the weight force measuring device 3 generates an output that depends on the weight of the semiconductor wafer 7. Therefore, the weight of the semiconductor wafer 7 may be determined based on the output of the weight force measuring device 3.

The present inventor has realised that the measurement output of a semiconductor wafer weighing apparatus such as that illustrated in FIG. 1 may be negatively affected by acceleration of the apparatus or of a semiconductor wafer loaded on the apparatus (i.e. may have an error caused by the acceleration). For example, an apparatus such as that illustrated in FIG. 1 may be subjected to vibration, for example caused by an earthquake, by vibration of a building containing the apparatus caused by the effects of wind on the building, or caused by other causes, such as impacts, movement of heavy loads, explosions, etc.

Acceleration of the apparatus or of a semiconductor wafer loaded on the apparatus may lead to acceleration forces being applied to the apparatus or to the semiconductor wafer, and therefore to the weight force measuring device 3 of the apparatus. Such acceleration forces applied to the weight force measuring device 3 may be measured by the weight force measuring device 3 in the same way that weight forces are measured by the weight force measuring device 3, and therefore such acceleration forces may lead to erroneous weight force measurements when acceleration of the apparatus occurs during measurement of the weight of a semiconductor wafer.

Therefore, in a first embodiment of the present invention, as illustrated in FIG. 1, the known semiconductor wafer weighing apparatus of FIG. 1 is modified by the inclusion of a detector 9 for detecting acceleration of the apparatus. In this embodiment, the detector 9 is an accelerometer for measuring acceleration of the apparatus, e.g. for determining the acceleration of the apparatus. Of course, in other embodiments the detector 9 may be a different type of detector 9 for detecting acceleration of the apparatus. For example, the detector 9 may be a detector 9 for measuring the position or the velocity of the apparatus or of a semiconductor wafer loaded on the apparatus, both of which can be used to determine the acceleration and therefore the acceleration forces applied to the apparatus. Alternatively, the detector 9 may be a detector for directly measuring the acceleration forces applied to the apparatus or to a semiconductor wafer loaded on the apparatus, for example a force transducer.

In other embodiments, the weight force measuring device 3 may be used as the detector and therefore there may not be a separate detector 9 as illustrated in FIG. 2. Such an arrangement is illustrated in FIG. 2(b). In the embodiment of FIG. 2(b), acceleration of the apparatus or of a semiconductor wafer loaded on the apparatus may be detected based on the output of the weight force measuring device 3 itself. For example, if the apparatus is vibrated, this will be apparent from the output of the weight force measuring device 3, which may show e.g. a periodically varying weight of a semiconductor wafer 7 loaded on the weight force measuring device 3.

In other embodiments the detector may not be part of the apparatus. Instead, the detector may be spaced apart from the apparatus, and may be part of a different apparatus, for example a weight force measuring device of a different apparatus. The detector may be in wired or wireless communication with the apparatus. In this manner, a single detector may be used with a plurality of different apparatus, for example apparatus that are all located in the same building and therefore are likely to be affected in the same way by a vibration affecting the whole building, for example a vibration due to an earthquake or due to wind. This may reduce the number of detectors that are needed and therefore reduce the complexity.

Preferably, whatever the type or positioning/location of the detector 9 the detector 9 is arranged to detect (e.g. measure) acceleration of the apparatus or of a semiconductor wafer loaded on the apparatus in a direction parallel to a weight measurement direction of the weight force measuring device 3. For example, in FIGS. 2(a) and 2(b) the weight force measuring device 3 is configured to measure a vertical component of a weight force, i.e. a vertical gravitational force. Therefore, accelerations of the apparatus or semiconductor wafer 7 occurring horizontally (i.e. perpendicular to the weight measurement direction) may not significantly affect the measurement output of the apparatus. In contrast, accelerations occurring vertically (i.e. parallel to the weight measurement direction), or accelerations having a significant vertical component, may have a significant effect on the measurement output of the apparatus, because the acceleration forces will be applied in the weight measurement direction of the apparatus. Therefore, it is advantageous to detect (or measure) accelerations (or a component of an acceleration) in a direction parallel to the weight measurement direction.

The apparatus further comprises a controller (not shown), e.g. a processing device such as a computer processor, for controlling an operation of the apparatus on the basis of the output of the detector 9.

Other features of the first embodiment that are the same as, or correspond to, features of the known apparatus of FIG. 1 are shown with the same reference numbers and description thereof is not repeated.

In one embodiment the controller may monitor and/or track the effects of acceleration of the apparatus or of a semiconductor wafer loaded on the apparatus on measurements performed by the apparatus. For example, the controller may identify (or control the apparatus to identify) a measurement that may have been affected by acceleration of the apparatus or of a semiconductor wafer loaded on the apparatus, e.g. a measurement that was being performed by the apparatus when acceleration was detected. Identifying a measurement that may have been affected by acceleration of the apparatus or of a semiconductor wafer loaded on the apparatus may comprise notifying an operator, controller, or host of the apparatus, for example by illuminating a light, making a sound, or displaying a message or indication on a display of the apparatus. This may allow an operator of the apparatus to know when a measurement has been affected by acceleration of the apparatus or of a semiconductor wafer loaded on the apparatus, so that the measurement result may be disregarded or the measurement may be repeated if necessary.

In another embodiment (or in addition or alternatively to the first embodiment) the controller may determine a time at which to perform a measurement based on the output of the detector 9. For example, the controller may control the apparatus to perform a measurement when the output of the detector 9 indicates substantially zero acceleration of the apparatus, or acceleration with a magnitude below a predetermined threshold value. By performing a measurement when the acceleration is substantially zero, there may be substantially no acceleration forces applied to the weight force measuring device 3 when performing the weight measurement, and therefore there may be substantially no error in the measurement result due to acceleration of the apparatus. The apparatus may control the apparatus to perform a measurement when the output of the detector 9 indicates that the magnitude of the acceleration has been substantially zero for a predetermined period of time.

Where there are a plurality of different vibrations of different wavelengths and directions affecting the apparatus or a semiconductor wafer loaded on the apparatus, the controller may be configured to control the apparatus to perform a measurement when the different vibrations sum to a substantially zero acceleration (i.e. a null beat) or when they sum so that their component in a weight measurement direction of the apparatus is substantially zero.

In another embodiment, the controller may correct the measurement results of the apparatus for the effects of acceleration of the apparatus or of a semiconductor wafer loaded on the apparatus. In other words, the controller may determine (or may control the apparatus to determine) an error in a measurement result caused by the effects of acceleration of the apparatus or of a semiconductor wafer loaded on the apparatus when the measurement was performed, and may correct the measurement result by subtracting the determined error. For example, the controller may determine (or may control the apparatus to determine) an error in a measurement performed by the weight force measurement device 3 caused by acceleration forces being applied to the weight force measurement device 3 during acceleration of the apparatus or of a semiconductor wafer loaded on the apparatus (or due to a relative acceleration between the apparatus and the semiconductor wafer).

The error in the measurement result may be determined using a predetermined relationship between the output of the weight force measuring device 3 due to acceleration of the apparatus or of a semiconductor wafer loaded on the apparatus and the acceleration of the apparatus or of a semiconductor wafer loaded on the apparatus. For example, in one embodiment the predetermined relationship may be an equation or algorithm that outputs the error in the output of the weight force measuring device 3 for an acceleration of the weight force measuring device 3 or of a semiconductor wafer loaded on the apparatus when that acceleration is entered into the equation or algorithm. This predetermined relationship may be determined in advance by accelerating (e.g. vibrating) the weight force measuring device 3 or of a semiconductor wafer loaded on the apparatus and measuring the output of the weight force measuring device 3 for different accelerations and/or frequencies of vibrations, in order to characterise the response of the weight force measuring device 3 to acceleration or vibration.

In another embodiment, the predetermined relationship may comprise a data file in which values of the error in the output of the weight force measuring device due to acceleration are associated with values of the acceleration. For example, the data file may comprise a list or a table, for example a look-up table.

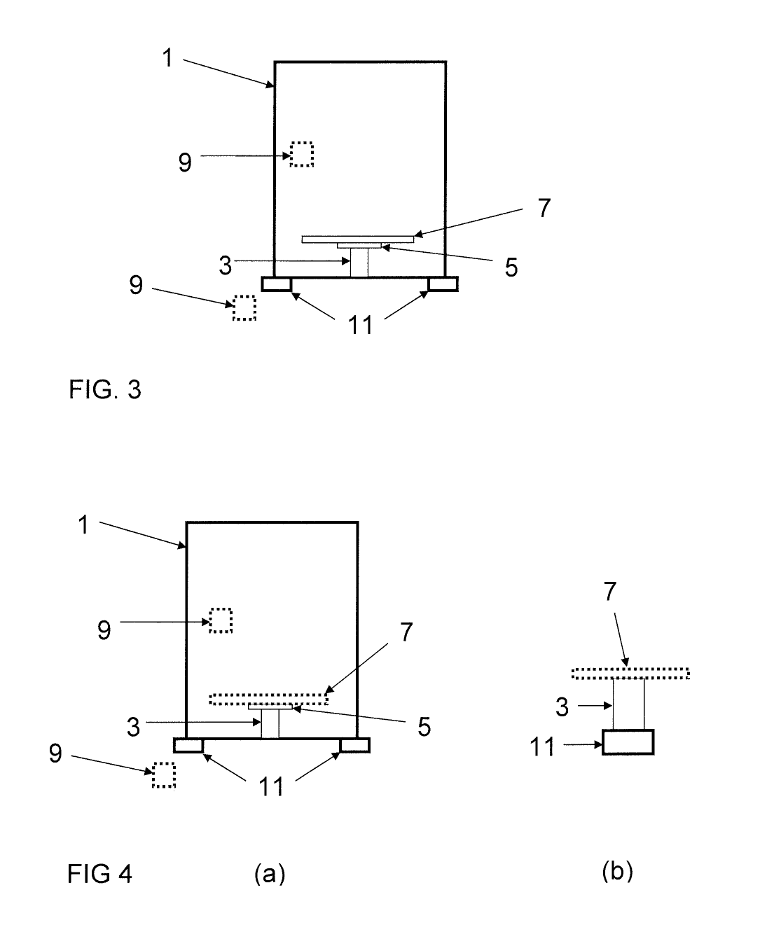

FIG. 3 is a schematic illustration of a semiconductor wafer weighing apparatus according to another embodiment of the present invention. In this embodiment, the apparatus further comprises active damping devices 11 for actively damping acceleration or vibration of the apparatus or of a semiconductor wafer loaded on the apparatus. In this embodiment, the active damping devices 11 are piezoelectric actuators. Of course, in other embodiments other active damping devices 11, for example other types of actuator, may be used instead of piezoelectric actuators.

Other features of this embodiment that are the same as, or correspond to, features of the known apparatus of FIG. 1 or the first embodiment of FIG. 2 are shown with the same reference numbers, and description thereof is not repeated.

The active damping devices 11 are controlled based on the output of the detector 9 to actively damp acceleration or vibration of the apparatus or of a semiconductor wafer loaded on the apparatus. Actively damping acceleration or vibration of the apparatus or of a semiconductor wafer loaded on the apparatus may comprise actively dissipating energy (e.g. kinetic energy) from the apparatus or of a semiconductor wafer loaded on the apparatus in order to reduce the acceleration or vibration of the apparatus. In this embodiment, energy is dissipated from the apparatus by applying forces to the apparatus using the piezoelectric actuators in order to counter (reduce) the acceleration or vibration of the apparatus. For example, where the apparatus is accelerating upwards, the piezoelectric actuators may provide a downwards force to counter this acceleration.

As shown in FIG. 3, in some embodiments the detector 9 may be positioned on the apparatus, or on a portion of the apparatus that is damped by the active damping devices 11. In this arrangement, the active damping devices 11 may be controlled to try to reduce the acceleration detected by the detector 9 to zero. In other embodiments, the detector 9 may be positioned outside of the apparatus, or on a portion of the apparatus that is not damped by the active damping devices 11. In this arrangement, the active damping devices 11 may be controlled to counteract, or reduce, the acceleration detected by the detector 9, so that the apparatus is less affected by the acceleration. Of course, as discussed above, in some embodiments the detector 9 may be separate from the apparatus and may be positioned spaced from the apparatus.

FIG. 4 (a) is a schematic illustration of an embodiment of a method of characterising the response of a weight force measuring device of a semiconductor wafer weighing apparatus to acceleration of the weight force measuring device or of a semiconductor wafer loaded on the weight force measuring device.

Features of this embodiment that are the same as, or correspond to, features of the known apparatus of FIG. 1 or the other embodiment of FIGS. 2 and 3 are shown with the same reference numbers, and description thereof is not repeated.

As discussed above in relation to other embodiments, in order to determine the error in the output of the apparatus due to acceleration of the apparatus or of a semiconductor wafer loaded on the apparatus it is helpful to know how the output of the apparatus is affected by acceleration of the apparatus or of a semiconductor wafer loaded on the apparatus. This can be determined by accelerating the weight force measuring device 3 with different accelerations and measuring the output of the weight force measuring device 3 as it is being accelerated.

In this embodiment, the response of the weight force measuring device 3 is characterised by vibrating the apparatus using the piezoelectric actuators 11 at different frequencies of vibration and measuring the output of the weight force measuring device 3 as it is being vibrated. Vibrating the apparatus means that accelerations of different magnitudes and directions are applied to the apparatus, and the output of the weight force measuring device 3 can therefore be measured for different accelerations of the weight force measuring device 3.

The characterisation may be carried out with a semiconductor wafer 7 loaded on to the weight force measuring device 3, in order to characterise how the weight force measuring device 3 responds to acceleration when it has a semiconductor wafer loaded on it, as it would when being used to perform measurements of semiconductor wafer weights. In addition, or alternatively, the characterisation may instead be carried out without a semiconductor wafer 7 loaded on the weight force measuring device 3, to characterise how the weight force measuring device 3 response to acceleration when it does not have a semiconductor wafer loaded on it. Such information may be useful in practice e.g. when taking a zero reading with no wafer loaded on the weight force measuring device 3.

In other embodiments where a semiconductor wafer is loaded on the weight force measuring device 3, the semiconductor wafer may be directly accelerated or vibrated rather than the weight force measuring device, and the output of the weight force measuring device may be determined for different accelerations of the semiconductor wafer.

The information obtained from accelerating the apparatus or a semiconductor wafer loaded on the apparatus by different accelerations (e.g. by vibrating the apparatus or semiconductor wafer) and measuring the output of the weight force measuring device 3 can be used to determine a relationship between the error in the output of the weight force measuring device 3 due to an acceleration of the weight force measuring device 3 or of a semiconductor wafer loaded on the apparatus and the acceleration of the weight force measuring device or of a semiconductor wafer loaded on the apparatus. For example, this relationship may be in the form of an equation, for example an equation that approximates the best-fit line of a graph of the output of the weight force measuring device 3 plotted against the acceleration of the weight force measuring device 3 or of a semiconductor wafer loaded on the apparatus. Alternatively, the relationship may be in the form of a program or algorithm, the input of which is the acceleration of the weight force measuring device 3 or of a semiconductor wafer loaded on the apparatus and the output of which is the error in the output of the weight force measuring device 3 due to the effects of the acceleration.

Alternatively, the relationship may be in the form of a data file in which values for the error in the output of the weight force measuring device 3 due to acceleration are related to, or stored in association with, values for the acceleration of the weight force measuring device 3 or of a semiconductor wafer loaded on the apparatus.

As discussed above, such relationships may be used to determine the error in a weight force measurement due to acceleration of the apparatus or of a semiconductor wafer loaded on the apparatus based on the acceleration of the weight force measuring device 3 or of the semiconductor wafer. Thus, where this relationship is known, the weight force measurement can be corrected for the effects of acceleration of the weight force measuring device 3 or of a semiconductor wafer loaded on the apparatus based on the measurement of the acceleration of the weight force measuring device 3 or of a semiconductor wafer loaded on the apparatus.

FIG. 4 (b) is a schematic illustration of an alternative embodiment of a method of characterising the response of a weight force measuring device of a semiconductor wafer weighing apparatus to acceleration of the weight force measuring device or of a semiconductor wafer loaded on the apparatus. The principle behind the method of FIG. 4 (b) is the same as the principle behind the method of FIG. 4 (a) discussed above, except that in this embodiment the weight force measuring device 3 is directly vibrated by a piezoelectric actuator 11 in order to characterise the response of the weight force measuring device 3 to acceleration of the weight force measuring device 3 or of a semiconductor wafer loaded on the apparatus.

Of course in other embodiments the positions and/or amounts of active damping devices 11 may be different to the positions and/or amounts illustrated in the FIGS.

Furthermore, in other embodiments the number and/or position of detector 9 may be different. For example, in other embodiments the detector 9 may be attached directly to the weight force measuring device 3, in order to directly detect the acceleration of the weight force measuring device 3.

In some embodiments, a plurality of apparatus such as those illustrated in FIGS. 2 and 3 may share the same detector 9. For example, the plurality of apparatus may be located in the same room or building, such that they may be affected in the same way by a vibration affecting the room or building, e.g. a vibration caused by an earthquake or by the effects of wind.

1. A semiconductor wafer weighing apparatus comprising:
a weight force measuring device for measuring a weight force of a semiconductor wafer; and
control means configured to control an operation of the apparatus based on detection of acceleration of the apparatus or of a semiconductor wafer loaded on the apparatus by a detector for detecting acceleration of the apparatus or of a semiconductor wafer loaded on the apparatus;
wherein:
the control means is arranged to determine an error in the output of the weight force measuring device caused by an acceleration of the apparatus or of a semiconductor wafer loaded on the apparatus, using a predetermined relationship that matches the error in the output of the weight force measuring device to acceleration of the apparatus or of a semiconductor wafer loaded on the apparatus for different accelerations of the apparatus or of a semiconductor wafer loaded on the apparatus.

2. The apparatus according to claim 1, wherein the control means is arranged to control the apparatus to substantially correct a measurement result of the apparatus for the effect of an acceleration of the apparatus or of a semiconductor wafer loaded on the apparatus.

3. The apparatus according to claim 1, wherein:
the apparatus comprises a detector for detecting acceleration of the apparatus or of a semiconductor wafer loaded on the apparatus; and
the control means is configured to control the operation of the apparatus based on detection of acceleration of the apparatus or of a semiconductor wafer loaded on the apparatus by the detector.

4. The apparatus according to claim 1, wherein:
the detector comprises the weight force measuring device; and
the control means is configured to control the operation of the apparatus based on detection of acceleration of the apparatus or of a semiconductor wafer loaded on the apparatus by the weight force measuring device.

5. The apparatus according to claim 1, wherein the predetermined relationship comprises:
an algorithm or an equation that outputs an error in the output of the weight force measuring device when an acceleration of the apparatus or of a semiconductor wafer loaded on the apparatus is input into the equation or algorithm; or
a data file in which a plurality of values of accelerations of the apparatus or of a semiconductor wafer loaded on the apparatus are associated with corresponding values of errors in the output of the weight force measuring device.

6. (canceled)

7. The apparatus according to claim 1, wherein the predetermined relationship is determined in advance by measuring the response of the weight force measuring device to different accelerations of the apparatus of or a semiconductor wafer loaded on the apparatus.

8-9: (canceled)

10. The apparatus according to claim 1, wherein the detector comprises:
an accelerometer for measuring acceleration of the apparatus or of a semiconductor wafer loaded on the apparatus; or
a force sensor for measuring a force applied to the apparatus or to a semiconductor wafer loaded on the apparatus; or
a position sensor for measuring a position of the apparatus or of a semiconductor wafer loaded on the apparatus; or
a velocity sensor for measuring a velocity of the apparatus or of a semiconductor wafer loaded on the apparatus.

11-12: (canceled)

13. A semiconductor wafer weighing method comprising:
detecting acceleration of a semiconductor wafer weighing apparatus or of a semiconductor wafer loaded on the apparatus using a detector; and
controlling an operation of the apparatus based on detection of acceleration of the apparatus or of a semiconductor wafer loaded on the apparatus by the detector;
wherein:
the apparatus comprises a weight force measuring device for measuring a weight force of a semiconductor wafer; and
the method comprises determining an error in the output of the weight force measuring device caused by an acceleration of the apparatus or of a semiconductor wafer loaded on the apparatus, using a predetermined relationship that matches the error in the output of the weight force measuring device to an acceleration of the apparatus or of a semiconductor wafer loaded on the apparatus for different accelerations of the apparatus or of a semiconductor wafer loaded on the apparatus.

14. The method according to claim 13, wherein the method comprises substantially correcting a measurement result for the effect of an acceleration of the apparatus or of a semiconductor wafer loaded on the apparatus.

15. The method according to claim 13, wherein the predetermined relationship comprises:
an algorithm or an equation that outputs an error in the output of the weight force measuring device when an acceleration of the apparatus or of a semiconductor wafer loaded on the apparatus is input into the equation or algorithm; or
a data file in which a plurality of values of accelerations of the apparatus or of a semiconductor wafer loaded on the apparatus are associated with corresponding values of errors in the output of the weight force measuring device.

16. (canceled)

17. The method according to claim 13, wherein the method comprises determining the predetermined relationship in advance by measuring the response of the weight force measuring device to different accelerations of the apparatus of or a semiconductor wafer loaded on the apparatus.

18. (canceled)

19. The method according to claim 13, wherein:
the apparatus comprises a detector for detecting acceleration of the apparatus or of a semiconductor wafer loaded on the apparatus; and
the method comprises controlling the operation of the apparatus based on detection of acceleration of the apparatus or of a semiconductor wafer loaded on the apparatus by the detector.

20. The method according to claim 13, wherein:
the detector comprises the weight force measuring device; and
the method comprises controlling the operation of the apparatus based on detection of acceleration of the apparatus or of a semiconductor wafer loaded on the apparatus by the weight force measuring device.

21. (canceled)

22. The method according to claim 13, wherein the method comprises detecting acceleration of the apparatus or of a semiconductor wafer loaded on the apparatus using:
an accelerometer for measuring acceleration of the apparatus or of a semiconductor wafer loaded on the apparatus; or
a force sensor for measuring a force on the apparatus or on a semiconductor wafer loaded on the apparatus; or
a position sensor for measuring a position of the apparatus or of a semiconductor wafer loaded on the apparatus; or
a velocity sensor for measuring a velocity of the apparatus or of a semiconductor wafer loaded on the apparatus.

23-24: (canceled)

25. A method of characterizing the response of a weight force measuring device of a semiconductor wafer weighing apparatus to acceleration of the weight force measuring device or of a semiconductor wafer loaded on the weight force measuring device, the method comprising:
determining a relationship that matches the output of the weight force measuring device to an acceleration of the weight force measuring device or of a semiconductor wafer loaded on the weight force measuring device, for different accelerations of the weight force measuring device or of a semiconductor wafer loaded on the weight force measuring device;
wherein determining the relationship comprises:
accelerating the weight force measuring device or a semiconductor wafer loaded on the weight force measuring device; and
measuring the output of the weight force measuring device in response to the acceleration.

26. The method according to claim 25, wherein the method comprises vibrating the weight force measuring device or a semiconductor wafer loaded on the weight force measuring device.

27. The method according to claim 25, wherein the method comprises measuring the output of the weight force measuring device for a plurality of different frequencies of vibration.

28. (canceled)

29. The method according to claim 25, wherein the relationship comprises:
an algorithm or an equation that outputs an error in the output of the weight force measuring device when an acceleration of the apparatus or of a semiconductor wafer loaded on the apparatus is input into the equation or algorithm; or
a data file in which a plurality of values of accelerations of the apparatus or of a semiconductor wafer loaded on the apparatus are associated with corresponding values of errors in the output of the weight force measuring device.

30. (canceled)

31. A semiconductor wafer weighing apparatus comprising:
control means configured to control an operation of the apparatus based on detection of acceleration of the apparatus or of a semiconductor wafer loaded on the apparatus by a detector for detecting acceleration of the apparatus or of a semiconductor wafer loaded on the apparatus;
wherein the control means is configured to:
predict when a continuously varying acceleration of the apparatus or of a semiconductor wafer loaded on the apparatus will be instantaneously substantially zero; and
control the apparatus to perform a measurement at the predicted time.

32. (canceled)

33. The semiconductor apparatus according to claim 31, wherein:
the apparatus is configured to record a plurality of values of the acceleration of the apparatus or of a semiconductor wafer loaded on the apparatus over a predetermined period of time; and
the control means is configured to use the recorded values to perform the prediction.

34. The semiconductor apparatus according to claim 33, wherein the control means is configured to determine an equation that best fits the recorded values and to use this equation to perform the prediction.

35: (canceled)

36. A semiconductor wafer weighing method comprising:
detecting acceleration of a semiconductor wafer weighing apparatus or of a semiconductor wafer loaded on the apparatus using a detector;
predicting when a continuously varying acceleration of the apparatus or of a semiconductor wafer loaded on the apparatus will be instantaneously substantially zero; and
controlling the apparatus to perform a measurement at the predicted time.

37. (canceled)

38. The method according to claim 36, wherein the method comprises:
recording a plurality of values of the acceleration of the apparatus or of a semiconductor wafer loaded on the apparatus over a predetermined period of time; and
using the recorded values to perform the prediction.

39. The method according to claim 38, wherein the method comprises determining an equation that best fits the recorded values and using this equation to perform the prediction.

40-42: (canceled)
